(19) United States
(12) Patent Application Publication
(10) Pub. No.: US 2018/0050515 A1
(43) Pub. Date: Feb. 22, 2018

(54) ACTIVE ESTER, THERMOSETTING RESIN COMPOSITION, PREPREG AND LAMINATED BOARD CONTAINING SAME

(71) Applicant: Shengyi Technology Co., Ltd., Guandong (CN)

(72) Inventors: Cheng LUO, Guangdong (CN); Guofang TANG, Guangdong (CN)

(21) Appl. No.: 15/563,185

(22) PCT Filed: Sep. 21, 2015
(86) PCT No.: PCT/CN2015/090080

§ 371 Date: Sep. 29, 2017

(30) Foreign Application Priority Data
Apr. 1, 2015 (CN) 201510152403.2

(51) Int. Cl. B32B 15/08; B32B 15/092; B32B 27/38; C08G 65/48; C08L 63/00; C08G 59/42; C08J 5/24; C08J 5/04; H05K 1/03

(52) U.S. Cl. CPC B32B 15/08; H05K 2201/012; B32B 27/38; C08G 65/485; C08L 63/00; C08G 59/4269; C08J 5/24; C08J 5/043; H05K 1/0366; B32B 2307/3065; B32B 2457/00; C08L 2201/02; C08L 2203/20; C08J 2363/00; C08J 2471/12; B32B 15/092

(57) ABSTRACT

The present invention provides an active ester, a thermosetting resin composition, a prepreg and a laminated board containing same. The active ester is a PPO main chain-containing double-ended polyfunctional active ester, and the thermosetting resin composition comprises epoxy resin and the PPO main chain-containing double-ended polyfunctional active ester. The prepreg, laminated board and copper-clad plate prepared from the thermosetting resin composition containing the PPO main chain-containing double-ended polyfunctional active ester have excellent dielectric properties, damp-heat resistance, heat resistance, extremely low water absorption and high bending strength.

### TECHNICAL FIELD

The present invention belongs to the technical field of copper clad laminates, especially relates to an active ester, and a thermosetting resin composition, a prepreg and a laminate comprising the same.

### BACKGROUND ART

In recent years, with the development of high performance, high functionality and networking of information and communication equipments, operation signal tends to be high frequency in order to achieve high-speed transmission and process large-capacity informations. In addition, in order to meet the development trends of all kinds of electronic products, circuit boards are developed toward a direction of high multi-layer and high wiring density. This requires that the substrate material not only has good dielectric properties (low dielectric constant and low dielectric loss tangent) to meet the need for high frequency transmission for signals, but also requires good heat resistance and machinability to meet the need of reliability and processability for multilayer printed circuit boards.

However, among the existing materials for printed circuit boards, epoxy resins are widely used as a main component to bond conventional epoxy resin circuit boards (FR-4 copper-clad laminates). Generally, due to the production of a large number of hydroxyl groups when using common curing agents, dielectric constant and dielectric loss tangent will be high (dielectric constant is 4.4, and dielectric loss tangent is about 0.02), and high frequency characteristics are not sufficient which cannot meet the requirement of high frequency for signal. Further, due to the production of hydroxyl groups, humidity-heat resistance of the board is poor.

JP Laid-Open Nos. 2002-012650 and 2003-082063 provide a series of active ester curing agents containing benzene ring, naphthalene ring or biphenyl structure as curing agents for epoxy resins, such as IAAN, IABN, TriABN and TAAN, and the resulting cured products have significantly reduced dielectric constant and dielectric loss value compared with traditional phenolics.

JP Patent Laid-Open No. 2003-252958 proposes that a cured product having reduced dielectric constant and dielectric loss value can be obtained by using biphenyl type epoxy and active ester as a curing agent, but heat resistance and glass transition temperature of the cured product are low.

JP Patent Laid-Open No. 2004-155990 obtains a polyfunctional active ester curing agent by reacting an aromatic carboxylic acid with an aromatic phenol, and a cured product having higher heat resistance, better dielectric constant and dielectric loss values can be obtained by curing phenolic epoxy using this active ester curing agent.

JP Patent Laid-Open No. 2009-235165 proposes that a cured product having higher heat resistance, better dielectric constant and dielectric loss value can be obtained by curing an epoxy containing an aliphatic structure using a polyfunctional active ester curing agent containing a dicyclopentadiene structure.

JP Patent Laid-Open No. 2009-040919 provides a thermosetting resin composition having dielectric constant stability and excellent conductive layer adhesion property. Main components of the composition include epoxy resin, active ester curing agent, accelerator and organic solvent. The usage amounts of epoxy resin and active ester were studied, and the relationships between the structures of epoxy resin and active ester and properties were not studied.

JP Patent Laid-Open Nos. 2009-242559, 2009-242560, 2010-077344, and 2010-077343 propose respectively that curing products having low moisture absorption, low dielectric constant and dielectric loss value can be obtained by using alkylated phenol or alkylated naphthol phenolic epoxy resin, biphenyl phenolic epoxy resin and active ester curing agent. WO2013056411A proposes that a cured product having higher heat resistance, better dielectric constant and dielectric loss value, and good humidity-heat resistance can be obtained by using an epoxy resin containing a naphthol structure, an active ester curing agent containing a dicyclopentadiene structure, and an accelerant.

CN102504201A proposes that a cured product having excellent heat resistance, dielectric properties, and humidity-heat resistance can be obtained by using a cyanate, an epoxy resin containing a naphthol structure, an active ester curing agent containing a dicyclopentadiene structure and an accelerant.

Although the prior arts mentioned above have proposed using an active ester as a curing agent for epoxy resins, which can improve humidity-heat resistance, reduce water absorption, and reduce dielectric constant and dielectric loss value of the cured products, they have a drawback that it is difficult to obtain a good balance between these properties, that is, make the cured products have good heat resistance, dielectric properties and low water absorption, and meanwhile have relatively stable dielectric properties as frequency variation.

CN1364821A discloses that small molecular polyphenylene ether capped by a small amount of benzoate is obtained by redistributing macromolecular PPO resin, and then the obtained resin is capped by an ester group containing double bonds. The curing and cross-linking group for obtaining such modified PPO resin comprises double bonds, which needs a free radical initiator to carry out curing and cross-linking and does not react with an epoxy resin at all.

CN102354546A discloses a curable composition comprising an alkene terminated ester-based polyphenylene ether, an epoxy resin and a curing agent, wherein the curing and cross-linking of the alkene terminated ester-based polyphenylene ether requires the presence of a free radical initiator, and the alkene terminated ester-based polyphenylene ether does not react with epoxy resin at all. Further, the curing of the epoxy resin therein requires an epoxy resin curing agent, for example, polyester or the like.

### CONTENTS OF THE INVENTION

Aiming at the problems in the prior art, the present invention provides a PPO main chain-containing double-ended polyfunctional active ester resin, a thermosetting resin composition comprising the active ester resin, and a prepreg, a laminate and a copper clad laminate prepared from the thermosetting resin composition. The thermosetting resin composition is capable of providing excellent dielectric properties, humidity-heat resistance, heat resistance and extremely low water absorption and higher bending strength required for high frequency and high speed copper clad laminates.

In order to achieve the above purpose, the present invention utilizes the following technical solutions:

A PPO main chain-containing double-ended polyfunctional active ester resin, having a structure of formula (1):

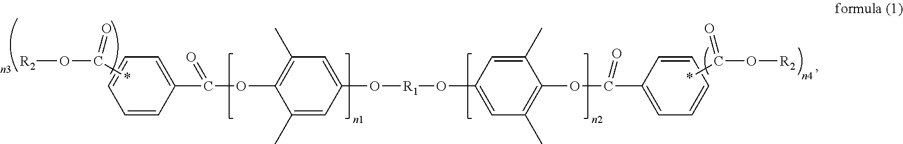

wherein, R₁ is

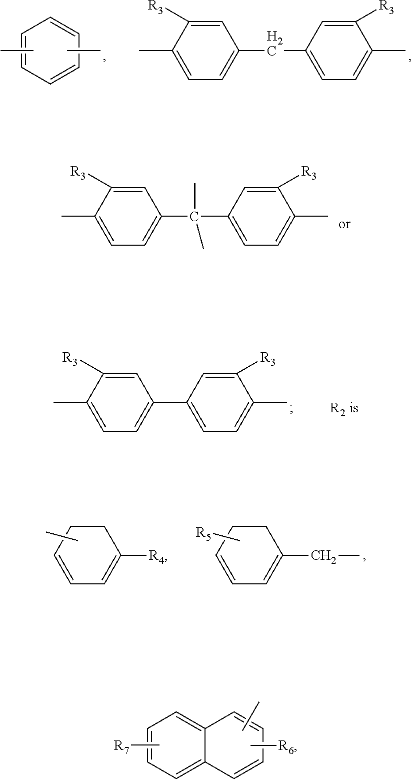

substituted or unsubstituted C1-C3 linear or branched alkyl, allyl or isopropenyl; R₃ is H, allyl or isopropenyl; R₄, R₅, R₆, R₇ are independently selected from the group consisting of H, substituted or unsubstituted C1-C3 linear or branched alkyl, allyl, isopropenyl and —O—R₈; R₈ is substituted or unsubstituted C1-C3 linear or branched alkyl or substituted or unsubstituted phenyl;
n1 and n2 are positive integers greater than 0 and satisfy 4≦n1+n2≦25, for example 5, 6, 7, 8, 9, 10, 11, 12, 13, 14, 15, 16, 17, 18, 19, 20, 21, 22, 23 or 24; n3 and n4 are identical or different, and are independently 1, 2 or 3.

Preferably, 6≦n1+n2≦20; preferably, 8≦n1+n2≦15.

Preferably, n3 and n4 are identical or different, and are independently 2 or 3; preferably, n3 and n4 are identical and are independently 2 or 3.

The present invention also provides a thermosetting resin composition comprising an epoxy resin and the PPO main chain-containing double-ended polyfunctional active ester resin as described above.

Preferably, in the thermosetting resin composition, the PPO main chain-containing double-ended polyfunctional active ester resin accounts for 10-80% of the total weight of the thermosetting resin composition, for example 15%, 20%, 25% 30%, 35%, 40%, 45%, 50%, 55%, 60%, 65%, 70% or 75%, preferably 30-75%.

Preferably, in the thermosetting resin composition, the epoxy resin accounts for 20-50% of the total weight of the thermosetting resin composition, for example, 23%, 27%, 31%, 35%, 38%, 40%, 42%, 45% or 48%.

Preferably, in the thermosetting resin composition, the epoxy resin refers to an epoxy resin having two or more epoxy groups per molecule, and specifically is, but not limited to, bisphenol A epoxy resin, bisphenol F epoxy resin, biphenyl epoxy resin, dicyclopentadiene epoxy resin, naphthalene epoxy resin, alicyclic epoxy resin, resorcinol epoxy resin, polyethylene glycol epoxy resin, trifunctional epoxy resin, brominated epoxy resin, tetrafunctional epoxy resin and phenolic epoxy resin, and other types of epoxy resins. One of the above epoxy resins can be used alone or two or more can be used in combination.

Preferably, the thermosetting resin composition may comprise, in addition to the epoxy resin, any one selected from the group consisting of cyanate ester resin, bismaleimide-triazine resin, 1,2-polybutadiene resin and styrene-butadiene resin, or a mixture of at least two of them, in an amount of 5-40%, for example 10%, 15%, 20%, 25%, 30% or 35%, of the total weight of the thermosetting resin composition.

Preferably, the thermosetting resin composition further comprises an organic additive flame retardant, and the organic additive flame retardant is a phosphorus-based flame retardant and/or a halogen-based flame retardant.

Preferably, the thermosetting resin composition further comprises a filler and/or a curing accelerator.

It is suggested that the filler is added in an amount of 0 to 5 times (not including 0) of the total mass of the PPO main chain-containing double-ended polyfunctional active ester resin, the epoxy resin and the above optional other thermosetting resin. The curing accelerator is 0.02 to 2% of the total mass of the PPO main chain-containing double-ended polyfunctional active ester resin, the epoxy resin and the above optional other thermosetting resin.

The term “comprise(s)/comprising” used in the present invention means that in addition to the components described, other components which give the thermosetting resin composition different characteristics can also be included. In addition, the term “comprise(s)/comprising” used in the present invention may also be replaced by a closed description of “is/being” or “consist(s) of/consisting of”.

For example, the thermosetting resin composition can also comprise a variety of additives, and as specific examples, antioxidant, heat stabilizer, antistatic agent, UV absorber, pigment, colorant, or lubricant and others can be listed. These additives can be used alone, and can also be used in the form of a mixture of two or more of them.

The present invention also provides the uses of the thermosetting resin composition as described above in prepregs, laminates, metal clad laminates and printed wiring boards.

A prepreg comprises a reinforcing material and the thermosetting resin composition as mentioned above which is attached thereon after impregnation and drying.

A laminate comprises at least one sheet of the prepreg as mentioned above. The laminate is obtained by bonding at least one sheet of the prepreg by heating and pressing.

A metal clad laminate comprises at least one sheet of the prepreg as mentioned above and a metal foil pressing on one side or both sides of superimposed prepregs.

A printed wiring board comprises at least one sheet of the prepreg as mentioned above.

Compared with the prior art, the present invention has the following beneficial effects:

Since the PPO main chain-containing double-ended polyfunctional active ester resin comprises a PPO structure which exhibits high heat resistance, good rigidity, good toughness, low water absorption and excellent electrical properties in its molecular structure, it is possible to ensure that the thermosetting resin composition has high heat resistance, low water absorption and excellent dielectric properties. Meanwhile, the PPO main chain-containing double-ended polyfunctional active ester resin comprises active ester functional groups capable of crosslinking with the epoxy resin without generating hydroxyl groups which is functional groups having large polarity and thus higher water absorption and worser dielectric properties, and thereby further ensures both excellent dielectric properties and low water absorption of the thermosetting resin composition. Further, the PPO main chain-containing double-ended polyfunctional active ester resin comprises 4 to 8 active ester functional groups in its molecular structure, and thus has more crosslinking points, enabling that the thermosetting resin composition has a large crosslinking density and further ensuring good heat resistance of the thermosetting resin composition.

The prepreg, laminate and copper clad laminate prepared by using the above thermosetting resin composition comprising the PPO main chain-containing double-ended polyfunctional active ester resin have excellent dielectric properties, humidity-heat resistance, heat resistance, extremely low water absorption and higher bending strength.

### EMBODIMENTS

The followings are specific embodiments of the present invention, and it should be noted that it will be apparent to those skilled in the art that a number of improvements and modifications may be made without departing from the principles of the embodiments of the present invention, and these improvements and modifications are also deemed to be in the protection scope of the present invention.

Hereinafter, the embodiments of the present invention will be described in further detail with reference to the following multiple examples. The examples of the present invention are not limited to the following specific examples. It is possible to change the implementation without departing from the scope of the claims.

### EXAMPLES

### (1) Redistribution of PPO

4000 g of toluene was heated to 100° C. with stirring in a three-necked flask equipped with a stirrer, a condensing reflux tube and a thermometer, and then 2000 g of PPO resin having a number average molecular weight of 20,000 was added. When the mixture became homogeneous, 600 g of diallyl bisphenol A (DABPA) was added, and the mixture was stirred for 30 min. Then 150 g of benzoyl peroxide (BPO) dissolved in toluene was added and the temperature was maintained at 92° C. for 360 min. The product was then cooled to room temperature and then 4000 ml of methanol was added and the mixture was stirred vigorously, filtered and dried to give 2400 g of a small molecular bifunctional PPO resin (A1).

Bifunctional PPO resins having different number average molecular weights can be obtained by repeating the above operations, changing the proportion of the reactants of redistributing the PPO resin and changing reaction temperature and reaction time, as shown in the following table:

| | A1 | A2 | A3 | A4 | A5 | A6 |
|---|---|---|---|---|---|---|
| PPO | 2000 | 2000 | 2000 | 2000 | 2000 | 2000 |
| DABPA | 600 | 480 | 360 | 320 | / | / |
| BPA | / | / | / | / | 300 | 240 |
| BPO | 150 | 150 | 150 | 120 | 100 | 80 |
| reaction | 92 | 100 | 90 | 100 | 90 | 92 |
| temperature/° C. | | | | | | |
| reaction time/min | 360 | 240 | 240 | 240 | 240 | 300 |
| Mn | 1304 | 1600 | 1909 | 2433 | 2658 | 3024 |

### (2) Acylation Reaction

530 g of trimesoyl chloride was charged into a 5000 ml three-necked flask equipped with a stirrer, a thermometer, a condenser (with a drying tube and a gas absorption device). Then the stirrer was started and the flask was slowly heated with oil bath. When trimesoyl chloride melted to be liquid state, 376 g of phenol was slowly added. At this time, the formed gas HCl escaped continuously and the contents seemed to have boiling phenomenon. When the reaction is not too intense, the reaction temperature was gradually increased to 120° C. and maintained for 1.5-2 h (until no HCl gas escaped). Then, 1000 g of the redistributed small molecular bifunctional PPO resin was added and the mixture was stirred and heated. After reacting for 2 h and the contents became cooler, the reaction mixture was gradually poured into 4000 ml of water with stirring, comminuted, filtered, washed with water, washed with ethanol and then dried to give 1345 g of the product, which is a PPO main chain-containing double-ended hexafunctional active ester resin B4 with an ester equivalent of 332 g/mol.

PPO main chain-containing double-ended polyfunctional active ester resins having different numbers of ester functional groups and different ester equivalents can be obtained by repeating the above operations, changing the redistributed PPO resins with different number average molecular weights and acyl chlorides and phenols, as shown in the following table:

| | B1 | B2 | B3 | B4 | B5 | B6 | B7 |
|---|---|---|---|---|---|---|---|
| Terephthaloyl chloride/g | 203 | 203 | | | | | |
| Trimesoyl chloride/g | | | | 530 | 530 | | |
| 1,2,4,5-benzene tetra acyl | | | 328 | | | 328 | 328 |
| chloride/g | | | | | | | |
| phenol/g | 94 | | 282 | 376 | | 282 | |
| p-hydroxyanisole/g | | 124 | | | 496 | | 372 |
| A1/g | | | | 1000 | | | |
| A2/g | 700 | | | | | | |
| A3/g | | 800 | 800 | | | | |
| A4/g | | | | | 2000 | | |
| A5/g | | | | | | 1200 | |
| A6/g | | | | | | | 1400 |
| number of ester | 4 | 4 | 8 | 6 | 6 | 8 | 8 |
| functional groups | | | | | | | |
| ester equivalent (g/mol) | 513 | 605 | 354 | 332 | 540.5 | 448.5 | 517 |

### Synthesis Comparative Example: Synthesis of ANCO-rPPE

3600 g of toluene was heated to 100° C. with stirring in a three-necked flask equipped with a stirrer, a condensing reflux tube and a thermometer, and then 3600 g of PPO resin having a number average molecular weight of 20,000 was added. When the mixture became homogeneous, 540 g of bisphenol A (BPA) was added, and the mixture was stirred for 30 min. Then 720 g of 75% aqueous benzoyl peroxide (BPO) solution was added and the contents were kept at a temperature of 100° C. to react for 120 min. The product was then cooled to room temperature and then 8000 ml of methanol was added and the mixture was stirred vigorously, filtered and dried to give 4000 g of bifunctional PPO resin having a number average molecular weight of 3400.

500 g of the above modified PPO resin was dissolved in 5000 ml of methylene chloride and 100 g of 50 wt % aqueous sodium hydroxide solution was added thereto. After 10 min, 49.9 g of tetrabutylammonium hydrogen sulfate (TBAHS) was added and the mixture was stirred at room temperature for 10 min, followed by the addition of 324.5 g of N,N-diallyl-2-chloroacetamide. After the reaction was carried out at room temperature for about 13 hours, 500 ml of deionized water was added, and the mixture was stirred for 30 min, then the aqueous layer was removed. The organic layer was washed with saturated brine, deionized water and concentrated to 1000 ml and then slowly poured into 5000 ml of methanol to precipitate. The obtained precipitate was washed twice with methanol and dried to give 500 g of ANCO-rPPE.

### (3) A Composition of a PPO Main Chain-Containing Double-Ended Polyfunctional Active Ester Resin and an Epoxy Resin

An epoxy resin, the PPO main chain-containing double-ended polyfunctional active ester resin obtained by the above-mentioned method, and a curing accelerator were uniformly mixed in a certain proportion in a solvent, and the solid content of the glue solution was controlled to be 65%. A 2116 glass cloth was impregnated into the above-mentioned glue solution and controlled to have an appropriate thickness, and then was baked in an oven at 115-175° C. for 2-15 minutes to prepare a prepreg. Then, several sheets of prepreg were stacked together with both sides thereof being stacked with copper foils, and were cured at a curing temperature of 170-250° C. and a curing pressure of 25-60 kg/cm² for 60-300 min to obtain a copper clad laminate, as shown in the following table.

| | Ex. | Ex. | Ex. | Ex. | Ex. | Ex. | Ex. | Ex. | Ex. |
|---|---|---|---|---|---|---|---|---|---|
| | 3-1 | 3-2 | 3-3 | 3-4 | 3-5 | 3-6 | 3-7 | 3-8 | 3-9 |
| B1 | 65 | 70 | | | | | | | |
| B2 | | | 75 | | 68 | | | | |
| B3 | | | | 75 | | | | | |
| B4 | | | | | | 55 | 55 | | |
| B5 | | | | | | | | 70 | |
| B6 | | | | | | | | | 60 |
| B7 | | | | | | | | | |
| ANCO-rPPE | | | | | | | | | |
| SA9000 | | | | | | | | | |
| HPC-8000-65T | | | | | | | | | |
| SA90 | | | | | | | | | |
| SA9000 | | | | | | | | | |
| HP-7200HHH | 35 | | | | 32 | 45 | | | 40 |
| HP-7200H-75M | | | | | | | 45 | | |
| NC-7300L | | 30 | | | | | | 30 | |
| SKE-3 | | | 25 | 25 | | | | | |
| DMAP | 0.08 | 0.08 | 0.08 | 0.08 | 0.08 | 0.08 | | | |
| 2E4MZ | | | | | | | 0.1 | 0.1 | 0.1 |
| Zinc | | | | | | | | | |
| isooctanoate | | | | | | | | | |

| | Ex. | Comp. | Comp. | Comp. | Comp. | Comp. |
|---|---|---|---|---|---|---|
| | 3-10 | Ex. 3-1 | Ex. 3-2 | Ex. 3-3 | Ex. 3-4 | Ex. 3-5 |
| B1 | | | | | | |
| B2 | | | 85 | | | |
| B2 | | | | | | |
| B4 | | | | | | |
| B5 | | | | | | |
| B6 | | | | | | |
| B7 | 80 | | | | | |
| ANCO-rPPE | | | | | 55 | |
| SA9000 | | | | | | 55 |
| HPC-8000-651 | | 55 | | | | |
| SA90 | | | | 50 | | |
| SA9000 | | | | | | |
| HP-7200HHH | | 45 | | | 45 | 45 |
| HP-7200H-75M | | | | 50 | | |
| NC-7300L | | | | | | |
| SKE-3 | 20 | | 15 | | | |
| DMAP | | 0.08 | 0.08 | 0.06 | 0.08 | 0.08 |
| 2E4MZ | 0.1 | | | | | |
| Zinc | | | | 1 | | |
| isooctanoate | | | | | | |

Properties of laminates are shown in the following table.

| | Ex. | Ex. | Ex. | Ex. | Ex. | Ex. | Ex. | Ex. | Ex. |
|---|---|---|---|---|---|---|---|---|---|
| | 3-1 | 3-2 | 3-3 | 3-4 | 3-5 | 3-6 | 3-7 | 3-8 | 3-9 |
| Tg (DMA) | 182 | 192 | 183 | 210 | 185 | 180 | 173 | 190 | 175 |
| Td (5% loss) | 381 | 380 | 382 | 380 | 384 | 380 | 373 | 380 | 372 |
| T288 | 38 | 40 | 33 | 60 | 38 | 35 | 28 | 40 | 27 |
| PCT/2 h | 3/3 | 3/3 | 3/3 | 3/3 | 3/3 | 3/3 | 3/3 | 3/3 | 3/3 |
| Water | 0.07 | 0.06 | 0.10 | 0.05 | 0.07 | 0.08 | 0.09 | 0.06 | 0.09 |
| absorption/% | | | | | | | | | |
| Dk (10 GHZ) | 3.75 | 3.7 | 3.6 | 3.55 | 3.75 | 3.8 | 3.85 | 3.7 | 3.85 |
| Df (10 GHZ) | 0.005 | 0.004 | 0.0025 | 0.0020 | 0.005 | 0.007 | 0.0075 | 0.004 | 0.007 |

| | Ex. | Comp. | Comp. | Comp. | Comp. Ex. | Comp. Ex. |
|---|---|---|---|---|---|---|
| | 3-10 | Ex. 3-1 | Ex. 3-2 | Ex. 3-3 | 3-4 | 3-5 |
| Tg (DMA) | 182 | 165 | 155 | 140 | Laminate | Alkene |
| Td (5% loss) | 377 | 370 | 350 | 346 | cannot be | terminated |
| T288 | 25 | 10 | 5 | 22 | made, | ester-based |
| PCT/2 h | 3/3 | 3/3 | 3/0 | 3/0 | since | polyphenylene |
| Water | 0.08 | 0.13 | 0.08 | 0.1 | ANCO-rPPE | ether |
| absorption/% | | | | | does not react | does not react |
| Dk (10 GHZ) | 3.6 | 3.9 | 3.6 | 4.00 | with EP | with epoxy |
| Df (10 GHZ) | 0.002 | 0.011 | 0.002 | 0.0085 | | resin |

### Analysis of Properties:

As can be seen from the examples, optimally, the number of active ester functional groups was 8.

From the comparation of Comparative Example 1 and Example 6, it can be concluded that when the same epoxy resin was cured using different active ester curing agents with the same ratio, the cured system with B4 has enhanced heat resistance, since B4 contains PPO main chain which has strong rigidity.

### (4) A Composition of a PPO Main Chain-Containing Double-Ended Polyfunctional Active Ester Resin, an Epoxy Resin and a Cyanate Ester

An epoxy resin, an esterified PPO resin, a cyanate ester resin and a curing accelerator were uniformly mixed in a certain proportion in a solvent, and the solid content of the glue solution was controlled to be 65%. A 2116 glass cloth was impregnated into the above-mentioned glue solution and controlled to have an appropriate thickness, and then was baked in an oven at 115-175° C. for 2-15 minutes to prepare a prepreg. Then, several sheets of prepreg were stacked together with both sides thereof being stacked with copper foils, and were cured at a curing temperature of 170-250° C. and a curing pressure of 25-60 kg/cm² for 60-300 min to obtain a copper clad laminate, as shown in the following table.

| | Ex. | Ex. | Ex. | Ex. | Ex. | Ex. | Ex. |
|---|---|---|---|---|---|---|---|
| | 4-1 | 4-2 | 4-3 | 4-4 | 4-5 | 4-6 | 4-7 |
| B1 | | | 50 | | | | |
| B2 | | | | 50 | | 75 | |
| B3 | | | | | 50 | | |
| B4 | 50 | 10 | | | | | |
| B5 | | | | | | | 43 |
| B6 | | | | | | | |
| B7 | | | | | | | |
| SA9000 | | | | | | | |
| HPC-8000-65T | | | | | | | |
| HP-7200HHH | 45 | 50 | 40 | | | | |
| HP-7200H-75M | | | | 35 | 35 | | |
| NC-7300L | | | | | | | 37 |
| SKE-3 | | | | | | 20 | |
| CY-40 | 5 | 40 | 10 | | | | 20 |
| PT30S | | | | 15 | 15 | 5 | |
| HF-10 | | | | | | | |
| Silicon powder | 33.4 | 33.4 | 33.4 | 33.4 | 33.4 | 33.4 | 33.4 |
| DMAP | 0.08 | 0.08 | 0.08 | 0.08 | 0.08 | 0.08 | |
| Zinc isooctanoate | 0.003 | 0.024 | 0.006 | | | | 0.012 |
| Cobalt | | | | 0.009 | 0.009 | 0.003 | |
| acetylacetonate | | | | | | | |
| 2E4MZ | | | | | | | 0.1 |

| | Ex. | Ex. | Comp. | Comp. | Comp. | Comp. |
|---|---|---|---|---|---|---|
| | 4-8 | 4-9 | Ex. 4-1 | Ex. 4-2 | Ex. 4-3 | Ex. 4-4 |
| B1 | | | | | | |
| B2 | | | | | | |
| B3 | | | | | | |
| B4 | | | | 8 | | 25 |
| B5 | | | | | | |
| B6 | 35 | | 80 | | | |
| B7 | | 30 | | | | |
| SA9000 | | | | | | |
| HPC-8000-65T | | | | | 22 | |
| HP-7200HHH | | | | 41 | | |
| HP-7200H-75M | | | | | | |
| NC-7300L | 40 | | 18 | | 60 | |
| SKE-3 | | 40 | | | | 25 |
| CY-40 | | | | | | |
| PT30S | 50 | | | | | |
| HF-10 | 25 | 30 | 2 | 41 | 18 | |
| Silicon powder | 33.4 | 33.4 | | 33.4 | 33.4 | 33.4 |
| DMAP | | | 0.08 | 0.08 | 0.06 | 0.008 |
| Zinc isooctanoate | 0.015 | 0.018 | 0.001 | 0.024 | 0.015 | 0.015 |
| Cobalt | | | | | | |
| acetylacetonate | | | | | | |
| 2E4MZ | 0.1 | 0.1 | | | | |

Properties of laminates are shown in the following table.

| | Ex. | Ex. | Ex. | Ex. | Ex. | Ex. | Ex. |
|---|---|---|---|---|---|---|---|
| | 4-1 | 4-2 | 4-3 | 4-4 | 4-5 | 4-6 | 4-7 |
| Tg (DSC) | 183 | 200 | 186 | 192 | 202 | 193 | 202 |
| Td (5% loss) | 395 | 395 | 395 | 395 | 395 | 395 | 395 |
| T300/min | >60 | >60 | >60 | >60 | >60 | >60 | >60 |
| PCT/2 h | 3/3 | 3/3 | 3/3 | 3/3 | 3/3 | 3/3 | 3/3 |
| Water | 0.07 | 0.1 | 0.07 | 0.07 | 0.07 | 0.07 | 0.07 |
| absorption/% | | | | | | | |
| Dk (10 GHZ) | 3.8 | 3.85 | 3.8 | 3.8 | 3.8 | 3.7 | 3.75 |
| Df (10 GHZ) | 0.008 | 0.006 | 0.007 | 0.0050 | 0.0050 | 0.007 | 0.0053 |

| | Ex. | Ex. | Comp. Ex. | Comp. Ex. | Comp. Ex. | Comp. Ex. |
|---|---|---|---|---|---|---|
| | 4-8 | 4-9 | 4-1 | 4-2 | 4-3 | 4-4 |
| Tg (DSC) | 205 | 206 | 180 | 195 | 189 | 220 |
| Td (5% loss) | 395 | 390 | 375 | 330 | 388 | 400 |
| T300/min | >60 | >60 | 5 | 43 | 25 | >60 |
| PCT/2 h | 3/3 | 3/3 | 3/1 | 3/0 | 3/3 | 3/0 |
| Water | 0.07 | 0.10 | 0.07 | 0.3 | 0.15 | 0.20 |
| absorption/% | | | | | | |
| Dk (10 GHZ) | 3.7 | 3.8 | 3.75 | 3.85 | 3.75 | 3.85 |
| Df (10 GHZ) | 0.0055 | 0.005 | 0.006 | 0.0095 | 0.006 | 0.006 |

The informations relating to the materials and tradenames thereof are as follows.

HPC-8000-65T: DIC, DCPD active ester, ester equivalent: 223;
HP-7200HHH: DIC, DCPD epoxy resin, epoxy equivalent: 288;
HP-7200H-75M: DIC, DCPD epoxy resin, epoxy equivalent: 280;
NC-7300L: NIPPON KAYAKU, naphthol type phenolic epoxy resin, epoxy equivalent: 214;
SKE-3: Shang kete, Special Epoxy Resin, epoxy equivalent: 120;
SA90: SABIC, small molecular difunctional polyphenylene ether, hydroxyl equivalent: 850;
SA9000: SABIC, small molecular acrylate terminated polyphenylene ether, CY-40: Wuqiao Resin Plant, DCPD cyanate ester resin;
PT30S: LONCZ, phenolic cyanate ester resin;
HF-10: Shanghai Huifeng, bisphenol A cyanate ester resin;
DMAP: 4-dimethylaminopyridine;
2E4MZ: 2-ethyl-4-methylimidazole.

The applicant states that: the present invention illustrates the detailed method of the present invention by the above examples, but the present invention is not limited to the detailed method, that is, it does not mean that the present invention must be conducted relying on the above detailed method. Those skilled in the art should understand that any modification to the present invention, any equivalent replacement of each raw material of the present invention and the addition of auxiliary ingredient, the selection of specific embodiment and the like all fall into the protection scope and the disclosure scope of the present invention.

1.-10. (canceled)

11. A PPO main chain-containing double-ended polyfunctional active ester resin, having a structure of formula (1): 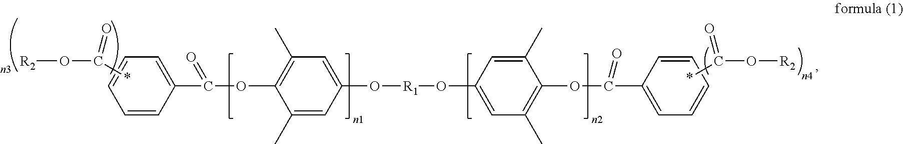
wherein, R₁ is 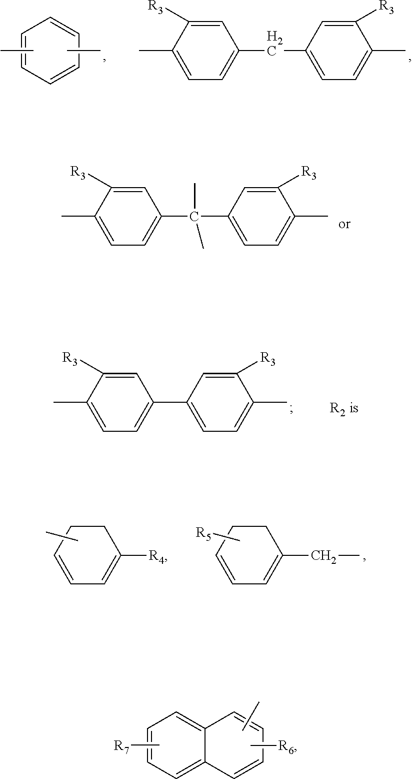
substituted or unsubstituted C1-C3 linear or branched alkyl, allyl or isopropenyl; R₃ is H, allyl or isopropenyl; R₄, R₅, R₆, R₇ are independently selected from the group consisting of H, substituted or unsubstituted C1-C3 linear or branched alkyl, allyl, isopropenyl and —O—R₈; R₈ is substituted or unsubstituted C1-C3 linear or branched alkyl or substituted or unsubstituted phenyl;
n1 and n2 are positive integers greater than 0 and satisfy 4≦n1+n2≦25; n3 and n4 are identical or different, and are independently 1, 2 or 3.

12. The active ester resin of claim 11, characterized in that 6≦n1+n2≦20.

13. The active ester resin of claim 11, characterized in that 8≦n1+n2≦15.

14. The active ester resin of claim 11, characterized in that n3 and n4 are identical or different, and are independently 2 or 3.

15. The active ester resin of claim 11, characterized in that n3 and n4 are identical and are independently 2 or 3.

16. A thermosetting resin composition comprising an epoxy resin and the PPO main chain-containing double-ended polyfunctional active ester resin of claim 11.

17. The thermosetting resin composition of claim 16, characterized in that the PPO main chain-containing double-ended polyfunctional active ester resin accounts for 10-80% of the total weight of the thermosetting resin composition.

18. The thermosetting resin composition of claim 16, characterized in that the epoxy resin accounts for 20-50% of the total weight of the thermosetting resin composition.

19. The thermosetting resin composition of claim 16, characterized in that the thermosetting resin composition further comprises any one selected from the group consisting of cyanate ester resin, bismaleimide-triazine resin, 1,2-polybutadiene resin and styrene-butadiene resin, or a mixture of at least two of them, in an amount of 5-40% of the total weight of the thermosetting resin composition.

20. The thermosetting resin composition of claim 16, characterized in that the thermosetting resin composition further comprises an organic additive flame retardant which is a phosphorus-based flame retardant and/or a halogen-based flame retardant.

21. The thermosetting resin composition of claim 16, characterized in that the thermosetting resin composition further comprises a filler and/or a curing accelerator.

22. A prepreg comprising a reinforcing material and the thermosetting resin composition of claim 16 which is attached thereon after impregnation and drying.

23. A laminate comprising at least one sheet of the prepreg of claim 22.

24. A metal clad laminate comprising at least one sheet of the prepreg of claim 22 and a metal foil pressing on one side or both sides of superimposed prepregs.

25. A printed wiring board comprising at least one sheet of the prepreg of claim 22.
